(19) United States
(12) Patent Application Publication
(10) Pub. No.: US 2023/0318053 A1
(43) Pub. Date: Oct. 5, 2023

(54) BATTERY INFORMATION SAMPLING ASSEMBLY, BATTERY MODULE, AND BATTERY PACK

(71) Applicant: BYD COMPANY LIMITED, Shenzhen (CN)

(72) Inventors: Yongnan WANG, Shenzhen (CN); Yi ZENG, Shenzhen (CN); Weixin ZHENG, Shenzhen (CN); Zhengyuan LIAO, Shenzhen (CN)

(21) Appl. No.: 18/207,897

(22) Filed: Jun. 9, 2023

Related U.S. Application Data
(63) Continuation of application No. PCT/CN2021/089036, filed on Apr. 22, 2021.

(30) Foreign Application Priority Data
Dec. 16, 2020 (CN) 202011487832.2

(51) Int. Cl. H01M 10/42; H05K 1/18; H05K 1/14; H01M 10/48

(52) U.S. Cl. CPC H01M 10/4257; H05K 1/189; H05K 1/147; H01M 10/482; H01M 2010/4271; H01M 2010/4278

(57) ABSTRACT

A battery information sampling assembly, includes a battery sampling controller and a flexible printed circuit board. The flexible printed circuit board is configured to collect information of a corresponding cell. The flexible printed circuit board is connected with the battery sampling controller.

### CROSS-REFERENCE TO RELATED APPLICATIONS

This application is a Continuation Application of International Patent Application No. PCT/CN2021/089036, filed on Apr. 22, 2021, which is based on and claims priority to and benefits of Chinese Patent Application No. 202011487832.2, filed on Dec. 16, 2020. The entire content of all of the above-referenced applications is incorporated herein by reference.

### FIELD

The present disclosure relates to the technical field of batteries, and specifically, to a battery information sampling assembly/component, a battery module, and a battery pack.

### BACKGROUND

In response to continuous development of new energy technologies, the application of battery modules/battery packs is becoming wider. In order to ensure the normal operation of a battery, it is necessary to collect information such as a voltage and a temperature of each cell in a battery module/battery pack and monitor an operating status of each cell, to ensure a safe operation of the battery module/battery pack.

In the existing technology, the circuit board is connected with a battery sampling controller through a wire harness. The configuration of the wire harness occupies an internal space of the battery module/battery pack, which reduces the energy density of the battery module/battery pack. In addition, the wire harness is prone to contact with relevant components in the battery module/battery pack. When the battery module/battery pack is used in a vehicle, the vibration of vehicle during travelling causes the wire harness to rub against relevant metal components. Long-term vibration and friction cause damages to the wire harness, which affects the normal use and safety of the battery module/battery pack.

### SUMMARY

The present disclosure resolves at least one of the technical problems in the related art. The present disclosure provides a battery information sampling assembly/component.

In a first aspect, a battery information sampling assembly is provided, which includes a battery sampling controller and a flexible printed circuit board. The flexible printed circuit board is configured to collect information of a corresponding cell. The flexible printed circuit board is connected with the battery sampling controller.

In a second aspect, a battery module is provided, which includes a cell and a battery support disposed on the cell, and further includes the battery information sampling assembly of the first aspect.

In a third aspect, a battery pack is provided, which includes a cell and a battery support disposed on the cell, and further includes the battery information sampling assembly of the first aspect.

Additional aspects and advantages of the present disclosure are provided in the following description, some of which will become apparent from the following description or may be learned from practices of the present disclosure.

### BRIEF DESCRIPTION OF THE DRAWINGS

The above and/or additional aspects and advantages of the present disclosure will become apparent and comprehensible from the description of the embodiments provided with reference to the following drawings.

FIG. 1 is a three-dimensional schematic structural diagram of a battery information sampling assembly/component according to an embodiment of the present disclosure.

FIG. 2 is a schematic structural cross-sectional view of the battery information sampling assembly according to an embodiment of the present disclosure.

FIG. 3 is a schematic structural diagram of a surface of the battery information sampling assembly according to an embodiment of the present disclosure.

FIG. 4 is a structural diagram of a cell and the battery information sampling assembly according to an embodiment of the present disclosure.

FIG. 5 is a schematic diagram of an assembly structure of the cell and the battery information sampling assembly of a battery module according to an embodiment of the present disclosure.

FIG. 6 is a schematic diagram of a battery pack according to an embodiment of the present disclosure.

### DETAILED DESCRIPTION

Embodiments of the present disclosure are described in detail below, and examples of the embodiments are shown in the drawings, where the same or similar elements or the elements having the same or similar functions are represented by the same or similar reference numerals throughout the description. The embodiments described below with reference to the drawings are examples and used only for explaining the present disclosure, and do not limit the present disclosure.

In the description of the present disclosure, it should be understood that orientation or position relationships indicated by the terms such as “center”, “up”, “down”, “left”, “right”, “vertical”, “horizontal”, “top”, “bottom”, “inside”, and “outside” are based on orientation or position relationships shown in the drawings, and are used only for ease and brevity of description of the present disclosure, rather than indicating or implying that the mentioned apparatus or element needs to have a particular orientation or needs to be included and operated in a particular orientation. Therefore, the terms do not limit the present disclosure.

It should be noted that the terms “first” and “second” are merely used for description, and do not indicate or imply relative importance or implicitly indicate a number of technical features that are indicated. Therefore, features defined by “first” and “second” may explicitly or implicitly include one or more such features. Further, in the description of the present disclosure, unless otherwise stated, “multiple” means two or more.

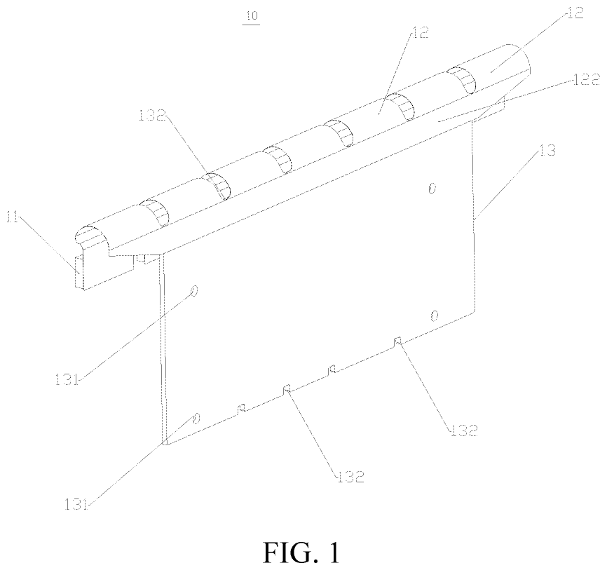

As shown in FIG. 1, the present disclosure discloses a battery information sampling assembly/component 10, including a battery sampling controller 13 and a flexible printed circuit board 12. The flexible printed circuit board 12 is configured to collect information about a corresponding cell, and the flexible printed circuit board 12 is directly connected with the battery sampling controller 13.

In the present disclosure, the battery sampling controller 13 is directly connected with the flexible printed circuit board 12, without a need to arrange/configure an additional wire harness to connect the battery sampling controller 13 to the flexible printed circuit board 12, which improves the space utilization of a battery module 20 or a battery pack 100 and indirectly improves the energy density of the battery module 20 or the battery pack 100. In addition, a problem of a failure of the battery information sampling assembly caused by wear of a wire harness as a result of external factors is avoided.

Multiple flexible printed circuit boards 12 may be provided in the battery module 20 or the battery pack 100. The multiple flexible printed circuit boards 12 are arranged/disposed at intervals. The multiple flexible printed circuit boards 12 are directly connected with the battery sampling controller 13.

The multiple flexible printed circuit boards 12 respectively collect battery information for each cell correspondingly and transmit the battery information directly to the battery sampling controller 13.

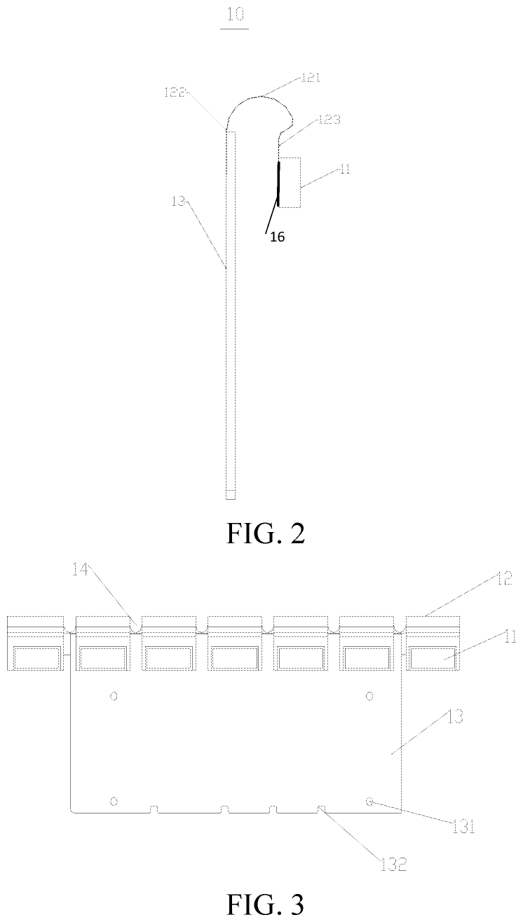

As shown in FIG. 2, in this embodiment of the present disclosure, the flexible printed circuit board 12 is overall as a structure of an upwardly arched “arch bridge”. The “arch bridge” structure of the flexible printed circuit board 12 can reduce the space occupied by the battery information sampling assembly in the battery module or the battery pack 100. The flexible printed circuit board 12 includes an upwardly arched bent portion 121 with a semicircular cross-section and a first connecting portion 122 and a second connecting portion 123 arranged/disposed on two opposite sides of the bent portion 121. The flexible printed circuit board 12 is connected with the battery sampling controller 13 through the first connecting portion 122, and the flexible printed circuit board 12 is connected with the cell through the second connecting portion 123.

It may be understood that the bent portion 121 of the flexible printed circuit board 12 may be arranged/disposed in a downwardly recessed and bent shape. No specific limitations are imposed, and any modification made based on the present disclosure and the actual situation should be protected by the present disclosure. In an embodiment of the present disclosure, the bent portions 121 of the multiple flexible printed circuit boards 12 are arranged/disposed at intervals, and the first connecting portions 122 of the multiple flexible printed circuit boards 12 are connected as a whole. The first connecting portions 122 of the multiple flexible printed circuit boards 12 are connected as a whole and then connected to the battery sampling controller 13. The design of the connecting the first connecting portions 122 of the multiple flexible printed circuit boards 12 as a whole can improve the reliability of the connection between the flexible printed circuit boards 12 and the battery sampling controller 13.

Certainly, the structure of the flexible printed circuit board 12 in the present disclosure is not limited thereto. In some embodiments, the first connecting portions 122 of the multiple flexible printed circuit boards 12 may be directly connected with the battery sampling controller 13 individually.

In this embodiment of the present disclosure, one battery sampling controllers 13 is provided, and multiple flexible printed circuit boards 12 are provided. For example, a number of the flexible printed circuit boards 12 and a number of cells are the same, and each of the flexible printed circuit board 12 collects battery information of one cell correspondingly. In this way, it can be ensured that a fault of one flexible printed circuit board 12 will not affect information collection of other cells by the battery information sampling assembly 10. In addition, the one-to-one connection between the flexible printed circuit boards 12 and the cells can ensure that in a case that some of the flexible printed circuit boards 12 fail, only the failed flexible printed circuit boards 12 need to be replaced, which is targeted and reduces the costs.

In another embodiment, the number of the flexible printed circuit boards 12 is inconsistent with the number of the cells, such that the number of the flexible printed circuit boards 12 is less than the number of the cells, that is, one flexible printed circuit board 12 collects battery information of multiple cells correspondingly. For example, one flexible printed circuit board collects battery information of two cells correspondingly. The correspondence between the flexible printed circuit boards and the cells may be properly selected based on actual requirements.

As shown in FIG. 1 and FIG. 4, in order to achieve quick connection between the battery information sampling assembly 10 and the cell 21, the battery information sampling assembly 10 further includes a plug 11 arranged/disposed on the flexible printed circuit board 12 and configured to be connected with the cell. The plug 11 is arranged on an end of the flexible printed circuit board 12. The plug 11 is inserted and assembled in a receptacle 211 on the cell 21 to achieve assembly and connection of the battery information sampling assembly 10 and the cell.

In the related art, the battery information sampling assembly is connected with the cell through welding. The process is complex and the assembly efficiency is low. The battery information sampling assembly 10 of the present disclosure can be quickly connected with the cell through the plug 11 arranged on the flexible printed circuit board 21, which improves the assembly efficiency of the battery information sampling assembly 10. The flexible printed circuit board 12 is connected with the plug 11 through the second connecting portion 123.

In an embodiment of the present disclosure, one plug 11 is correspondingly arranged/disposed on each of the flexible printed circuit boards 12, thereby realizing information collection of one cell by one flexible printed circuit board 12. In another embodiment of the present disclosure, multiple plugs 11 are arranged on each of the flexible printed circuit boards 12, thereby realizing information collection of multiple cells by one flexible printed circuit board 12.

Multiple plugs 11, for example, two, three, or other numbers of plugs may be arranged on each of the flexible printed circuit boards 12. A number may be properly selected based on actual requirements. The multiple plugs 11 are arranged side by side at fixed intervals on an end of one flexible printed circuit board 12.

The configuration of the multiple plugs 11 is not limited thereto, and may be adaptively adjusted according to the configuration of the cells to realize the convenient and firm insertion between the plugs 11 and the cells.

As shown in FIG. 1 and FIG. 3, in the present disclosure, the flexible printed circuit board 12 is welded to the battery sampling controller 13, and the plug 11 is welded to the flexible printed circuit board 12. A copper sheet on the flexible printed circuit board 12 is connected with a pin on the plug 11 through welding, and a pin led out from the battery sampling controller 13 is connected with the copper sheet on the flexible printed circuit board 12 through welding.

It may be understood that the way of connection between the flexible printed circuit board 12 and the battery sampling controller 13 and the way of connection between the plug 11 and the flexible printed circuit board 12 is not limited thereto.

The battery information sampling assembly 10 of the present disclosure further includes a reinforcing plate 16 arranged/disposed on a back side of the plug 11. The back side of the plug 11 is a side away from the cell. After the flexible printed circuit board 12 is welded to the plug 11, the reinforcing plate is fixedly connected with the flexible printed circuit board 12. The plug 11 is arranged on a surface (e.g., a first side) of the flexible printed circuit board 12, and the reinforcing plate is arranged on the other surface (e.g., a second side) of the flexible printed circuit board 12. The reinforcing plate is arranged on the other surface of the flexible printed circuit board 12 through adhesive. After the reinforcing plate is adhered to the flexible printed circuit board, adhesive is applied to an outer periphery of the reinforcing plate, the plug 11, and the flexible printed circuit board 12 to ensure firmer connection between the reinforcing plate, the plug 11, and the flexible printed circuit board 12.

In an embodiment of the present disclosure, the battery information sampling assembly 10 includes multiple reinforcing plates. One reinforcing plate is arranged on the back side of each of the plugs 11. In another embodiment of the present disclosure, the battery sampling assembly includes one reinforcing plate. Each of the plugs 11 is adhered and fixed to the reinforcing plate. In another embodiment of the present disclosure, the battery sampling assembly includes multiple reinforcing plates. Multiple plugs 11 are fixedly connected with each of the reinforcing plates.

In this embodiment of the present disclosure, the battery sampling controller 13 is a BIC (battery information collector) board, and a positioning hole 131 and an engagement position 132 are arranged/disposed on the BIC board. According to the battery information sampling assembly 10, a battery support 22 is positioned and assembled with the battery information sampling assembly 10 through the positioning hole 131 arranged/disposed on the battery sampling controller 13. The engagement position 132 is a groove, and a snap 221 on the battery support 22 is embedded into the engagement position 132 for engagement, so as to fix the battery information sampling assembly 10.

In this embodiment of the present disclosure, the battery sampling controller 13 includes four positioning holes 131. Multiple engagement positions 132 are evenly configured at fixed intervals on an upper edge and a lower edge of the battery sampling controller 13. Four engagement positions are configured on the upper edge of the battery sampling controller 13. Four engagement positions are configured on the lower edge of the battery sampling controller 13. The number of the engagement positions is not limited thereto, and may be adjusted based on actual requirements.

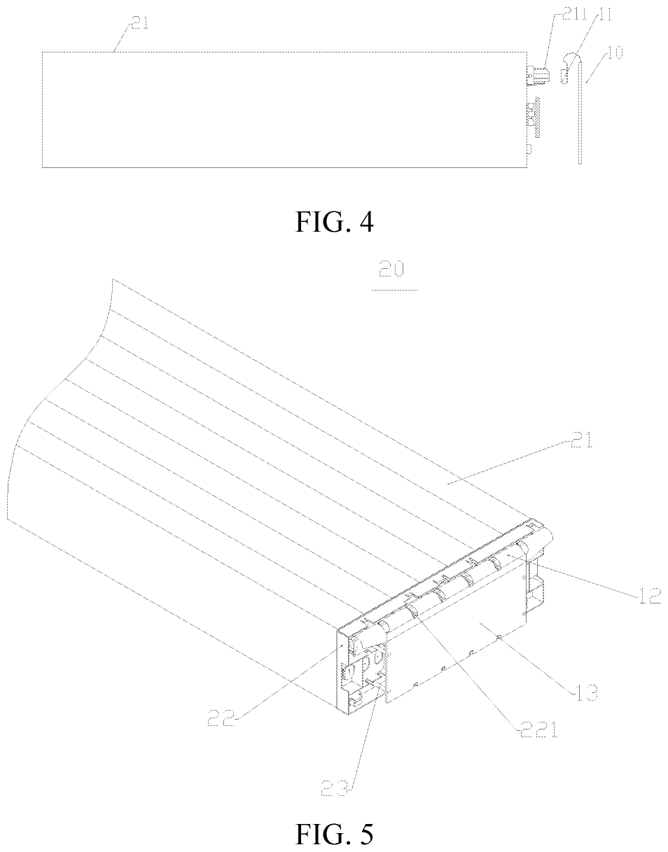

As shown in FIG. 4 and FIG. 5, a battery module 20 is provided. The battery module 20 includes multiple cells 21 stacked in sequence. A battery support 22 is arranged/disposed on ends of the multiple cells 21, and the ends of the multiple cells 21 extend into the battery support 22. The battery information sampling assembly is connected with receptacles 211 of the cells 21 through the plugs 11. One end of an assembly rod 23 is inserted into the positioning hole 131 of the battery sampling controller 13, and the other end extends into the battery support 22, to achieve the positioning and assembly of the battery sampling controller 13. Multiple assembly rods 23, for example, four assembly rods are provided. A snap 221 is arranged/disposed on the battery support 22. The snap 221 is embedded into the engagement position 132 on the battery sampling controller 13, to fix the battery sampling controller. A gap exists between the flexible printed circuit boards 12 of the battery information sampling assembly. The gap forms a snap avoidance position 14 on the battery support 22. A part of the snap 221 on the battery support 22 passes through the snap avoidance position 14 and fits the engagement position 132 on the upper edge of the battery sampling controller 13 to achieve the engagement. After the battery information sampling assembly 10 is assembled with the battery support 22, a protective cover (not shown in the figure) is assembled with the battery support 22 to protect the battery information sampling assembly.

The battery information sampling assembly 10 of the present disclosure collects battery parameter information such as a voltage and a temperature of each cell 21 through the flexible printed circuit board 12, and directly transmits the parameter information to the battery sampling controller 13. Finally, the parameter information is transmitted to a battery management system through the battery sampling controller 13, thereby realizing the monitoring of the cell.

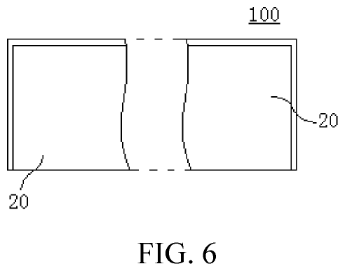

As shown in FIG. 6, a battery pack 100 includes the battery module 20 in the above embodiments.

The battery pack 100 in this embodiment of the present disclosure includes at least one battery module 20 using the above battery information sampling assembly 10. The battery information sampling assembly 10 can realize information collection for multiple cells 21 in multiple battery modules 20 in the battery pack 100, and has a higher operational stability, which can improve the safety of the battery pack 100, and the position and space occupation of the battery information collection assembly 10 are more proper, which can improve the space utilization of the battery pack 100 and improve the energy density of the battery pack 100.

Some of the embodiments of the present disclosure have been shown and described. A person of ordinary skill in the art should understand that various changes, modifications, replacements, and variations may be made to the embodiments without departing from the principles and spirit of the present disclosure, and the scope of the present disclosure is defined by the appended claims and their equivalents.

What is claimed is:

1. A battery information sampling assembly, comprising:
a battery sampling controller; and
a flexible printed circuit board, wherein the flexible printed circuit board is configured to collect information of a corresponding cell, and the flexible printed circuit board is connected with the battery sampling controller.

2. The assembly according to claim 1, further comprising a plurality of flexible printed circuit boards comprising the flexible printed circuit board, wherein
the flexible printed circuit boards are disposed at intervals, and
the flexible printed circuit boards respectively collect information of corresponding cells comprising the corresponding cell.

3. The assembly according to claim 1, further comprising a plug disposed on the flexible printed circuit board, wherein the flexible printed circuit board is connected with the corresponding cell through the plug.

4. The assembly according to claim 2, further comprising a plurality of plugs, wherein one of the plugs is disposed on each of the flexible printed circuit boards.

5. The assembly according to claim 3, wherein
the flexible printed circuit board is welded to the battery sampling controller; and
the plug is welded to the flexible printed circuit board.

6. The assembly according to claim 3, wherein
the flexible printed circuit board comprises a bent portion, a first connecting portion, and a second connecting portion, the first connecting portion and the second connecting portion are connected with the bent portion;
the flexible printed circuit board is connected with the battery sampling controller through the first connecting portion; and
the flexible printed circuit board is connected with the plug through the second connecting portion.

7. The assembly according to claim 3, further comprises a reinforcing plate configured to reinforce a connection between the flexible printed circuit board and the plug, wherein the reinforcing plate is disposed on a back side of the flexible printed circuit board.

8. The assembly according to claim 7, wherein
a first side of the flexible printed circuit board is connected with the plug; and
a second side of the flexible printed circuit board is connected with the reinforcing plate.

9. The assembly according to claim 1, wherein
a positioning hole is disposed on the battery sampling controller, and
the positioning hole is configured to assemble and position the battery information sampling assembly with the corresponding cell.

10. A battery module, comprising:
a cell;
a battery support disposed on the cell; and
a battery information sampling assembly, wherein the battery information sampling assembly comprises:
a battery sampling controller; and
a flexible printed circuit board is configured to collect information of a corresponding cell, and the flexible printed circuit board is connected with the battery sampling controller.

11. The module according to claim 10, wherein
the battery information sampling assembly comprises a plurality of flexible printed circuit boards comprising the flexible printed circuit board,
the flexible printed circuit boards are disposed at intervals, and
the flexible printed circuit boards respectively collect information of corresponding cells comprising the corresponding cell.

12. The module according to claim 10, wherein the battery information sampling assembly comprises a plug disposed on the flexible printed circuit board, and the flexible printed circuit board is connected with the corresponding cell through the plug.

13. The module according to claim 11, wherein the battery information sampling assembly comprises a plurality of plugs, wherein one of the plugs is disposed on each of the flexible printed circuit boards.

14. The module according to claim 12, wherein
the flexible printed circuit board is welded to the battery sampling controller; and
the plug is welded to the flexible printed circuit board.

15. The module according to claim 12, wherein
the flexible printed circuit board comprises a bent portion, a first connecting portion, and a second connecting portion, the first connecting portion and the second connecting portion are connected with the bent portion;
the flexible printed circuit board is connected with the battery sampling controller through the first connecting portion; and
the flexible printed circuit board is connected with the plug through the second connecting portion.

16. The module according to claim 12, wherein the battery information sampling assembly comprises a reinforcing plate configured to reinforce a connection between the flexible printed circuit board and the plug, wherein the reinforcing plate is disposed on a back side of the plug.

17. The module according to claim 16, wherein
a first side of the flexible printed circuit board is connected with the plug; and
a second side of the flexible printed circuit board is connected with the reinforcing plate.

18. The module according to claim 10, wherein
a positioning hole is disposed on the battery sampling controller, and
the positioning hole is configured to assemble and position the battery information sampling assembly with the corresponding cell.

19. A battery pack, comprising a battery module, wherein the battery module comprises:
a cell;
a battery support disposed on the cell; and
a battery information sampling assembly, wherein the battery information sampling assembly comprises:
a battery sampling controller; and
a flexible printed circuit board is configured to collect information of a corresponding cell, and the flexible printed circuit board is connected with the battery sampling controller.

20. The battery pack according to claim 19, wherein the battery information sampling assembly comprises a plug disposed on the flexible printed circuit board, and the flexible printed circuit board is connected with the corresponding cell through the plug.
